(19) United States
(12) Patent Application Publication
(10) Pub. No.: US 2009/0145650 A1
(43) Pub. Date: Jun. 11, 2009

(54) SCREEN MASK, METHOD FOR PRINTING CONDUCTIVE BONDING MATERIAL, MOUNTING METHOD OF MOUNTING DEVICES, AND MOUNTING SUBSTRATE

(76) Inventor: Kenichi NISHIKAWA, Osaka (JP)

Correspondence Address: BIRCH STEWART KOLASCH & BIRCH, PO BOX 747, FALLS CHURCH, VA, 22040-0747, US

(21) Appl. No.: 12/331,087

(22) Filed: Dec. 9, 2008

(30) Foreign Application Priority Data
Dec. 10, 2007 (JP) 2007-318811

(51) Int. Cl. H05K 1/11; B05C 11/00; B05D 5/12; H05K 3/30

(52) U.S. Cl. 174/261; 118/504; 427/58; 156/291

(57) ABSTRACT

A screen mask according to an embodiment of the present invention includes a mask member in which a print pattern is formed to print a conductive bonding material onto a mounting substrate. The mask member includes a first print area in which a conductive bonding material is printed onto the mounting substrate so as to have a first thickness, and a second print area in which the conductive bonding material is printed onto the mounting substrate so as to have a second thickness that is thicker than the first thickness.

### CROSS REFERENCE TO RELATED APPLICATIONS

This application claims priority under 35 U.S.C. § 119(a) on Patent Application No. 2007-318811 filed in Japan on Dec. 10, 2007, the entire contents of which are herein incorporated by reference.

### BACKGROUND OF THE INVENTION

The present invention relates to a screen mask for printing a conductive bonding material having different thicknesses onto a mounting substrate, a method for printing a conductive bonding material using such a screen mask, a mounting method of mounting devices in which mounting devices are mounted using such a screen mask or by such a method for printing a conductive bonding material, and a mounting substrate used in such a mounting method of mounting devices.

As functionality of electronic devices increases, electronic circuits (mounting devices) adopted to implement the functionality have come to have a higher density and a higher performance, and they are now required to have even still higher density and performance. The functionality of electronic devices is implemented by mounting (bonding) mounting devices including electronic circuits onto a mounting substrate.

Along with the increase in the density of electronic circuits, in order to mount mounting devices at a high density, flip-chip mounting is proposed in which a flip chip, or a chip that has been flipped, is mounted. In addition, a surface mounting device (SMD) whose bonding terminals are mounted directly on the surface of a mounting substrate is proposed.

FIGS. 8A to 8D are process diagrams illustrating the steps when conventional flip chip mounting is performed. FIG. 8A is a side view illustrating a state of a mounting substrate. FIG. 8B is a side view illustrating a state of a positioning step of positioning a flip chip to the mounting substrate. FIG. 5C is a side view illustrating a state of a flip chip bonding step of bonding the flip chip to land portions of the mounting substrate. FIG. 8D is a cross-sectional view illustrating a state of a flip chip fixing step of forming a fixing portion between the flip chip bonded to the mounting substrate and the mounting substrate to fix the flip chip.

A mounting substrate 120 includes gold-plated lead electrodes 125 formed by patterning a copper foil (FIG. 5A). On a flip chip 164 configured with a bare chip, for example, gold bumps 164p are formed so as to correspond to the lead electrodes 125 (FIG. 8B). The gold bumps 164p are positioned to face the corresponding lead electrodes 125 (FIG. 8B: a positioning step).

The gold bumps 164p (flip chip 164) are placed on the gold-plated lead electrodes 125, and by applying ultrasound vibrations (USV) from the outside, the gold bumps 164p are bonded to the lead electrodes 125 (mounting substrate 120) (FIG. 8C: a flip chip bonding step).

The flip chip 164 bonded to the lead electrodes 125 is fixed by a fixing portion 170 formed by injecting a filler (underfill) between the flip chip 164 and the mounting substrate 120 and thermally curing the applied underfill (FIG. 8D, a flip chip fixing step).

FIGS. 9A to 9F are process diagrams illustrating the steps when a conventional flip chip and a conventional surface mounting device are mounted on a single mounting substrate. FIG. 9A is a side view illustrating a state of a prepared mounting substrate. FIG. 9B is a side view illustrating a state of a conductive bonding material printing step of printing, onto the mounting substrate, a conductive bonding material that is to correspond to a surface mounting device. FIG. 9C is a side view illustrating a state of a flux preparing step of preparing a flux to be transferred onto solder bumps of a flip chip. FIG. 9D is a cross-sectional view illustrating a state of a flux transferring step of transferring the flux onto solder bumps of a flip chip. FIG. 9E is a cross-sectional view illustrating a state of a mounting device placing step of placing the flip chip and a surface mounting device onto the mounting substrate. FIG. 9F is a cross-sectional view illustrating a state of a mounting device bonding step of bonding the flip chip and the surface mounting device to the mounting substrate.

A mounting substrate 120 includes gold-plated lead electrodes 125f and 125s formed by patterning a copper foil (FIG. 9A). The lead electrode 125f is a pattern for bonding a flip chip 164 as a mounting device, and the lead electrode 125s is a pattern for bonding a surface mounting device 162 as a mounting device.

Solder bumps 152p are formed by printing a conductive bonding material onto the lead electrode 125s (FIG. 9B: a solder printing step).

On the other hand, a flux 180 to be transferred onto ball-shaped solder bumps 165 that have been formed on the gold bumps 164p of the flip chip 164 configured with a bare chip is prepared (FIG. 9C: a flux preparing step). The prepared flux 180 is transferred onto the solder bumps 165 to form transferred flux portions 180p (FIG. 9D: a flux transferring/forming step).

The flip chip 164 (the solder bumps 165) is positioned to and placed on the lead electrode 125f, and the surface mounting device 162 (bonding terminals 162p) is positioned to and placed on the lead electrode 125s (the solder bumps 152p) (FIG. 9E: a placing step).

The whole is heated to melt and solidify (solder reflow) the solder bumps 165, the transferred flux portions 180p and the solder bumps 152p so as to bond the flip chip 164 (the gold bumps 164p) and the surface mounting device 162 (the bonding terminals 162p) to the lead electrode 125f and the lead electrode 125s, respectively (FIG. 9F: a bonding step).

When producing a mixed mounting module by mounting a flip chip and a surface mounting device onto a mounting substrate in a mixed manner, the conventional example described above has a problem in that, because the flip chip and the surface mounting device employ mounting forms that are different from each other, a flip-chip mounting apparatus that bonds the flip chip is required in addition to a SMD mounting apparatus that bonds the surface mounting device (SMD), which requires a significant investment in equipment.

There is also another problem in that additional steps are required in the production, such as a fixing step of thermally curing a filler to fix a flip chip (FIG. 8D) and a flux transferring/forming step of transferring a flux onto solder bumps of a flip chip in order to reliably bond the flip chip (FIG. 9D), and as a result, the productivity decreases and the production cost increases.

Furthermore, the solder bumps of a flip chip are very small in size, and thus the adhesion between the flux transferred to the solder bumps and the mounting substrate (lead electrode) is insufficient, resulting in a problem of low yield in flip-chip mounting.

A conventional example of mounting a bare chip (flip chip) and a surface mounting device (SMD) in a mixed manner is disclosed in, for example, JP H11-135934A, and a conventional example of printing solder having different thicknesses onto a mounting substrate using different screen masks is disclosed in, for example, JP 2001-60763A.

### SUMMARY OF THE INVENTION

The present invention has been conceived in light of such circumstances, and it is an object of the present invention to provide a screen mask with which a conductive bonding material can be formed with good work efficiency.

It is another object of the present invention to provide a method for printing a conductive bonding material, with which it is possible to print a conductive bonding material having different thicknesses onto a mounting substrate with ease, high accuracy and good productivity.

It is another object of the present invention to provide a mounting method of mounting devices, with which it is possible to efficiently mount mounting devices of different mounting forms with high accuracy and improve productivity.

It is another object of the present invention to provide a mounting substrate that can prevent contact of a conductive bonding material between flat terminals of a bumpless flip chip and that can provide a mounting substrate having a high bonding yield.

A screen mask according to the present invention is a screen mask for printing a conductive bonding material onto a mounting substrate, including a mask member in which a print pattern is formed, wherein the mask member includes: a first print area in which the conductive bonding material is printed onto the mounting substrate so as to have a first thickness, and a second print area in which the conductive bonding material is printed onto the mounting substrate so as to have a second thickness that is thicker than the first thickness.

With this configuration, it is possible to form a conductive bonding material patterned to have thicknesses corresponding to the mounting forms (bonding forms) of mounting devices to be mounted onto a mounting substrate, and the conductive bonding material can be formed with good work efficiency.

Furthermore, in the screen mask of the present invention, it is preferable that the mask member includes a metal material layer and a resin material layer formed on a surface of the metal material layer that faces the mounting substrate.

With this configuration, it is possible to improve the adhesion of the mask member to the mounting substrate.

Furthermore, in the screen mask of the present invention, it is preferable that a border step portion located between the first print area and the second print area has a chamfer portion.

With this configuration, it is possible to suppress abrasion of a squeegee used when forming a conductive bonding material, and the durability and print stability can be secured.

Furthermore, in the screen mask of the present invention, it is preferable that the second print area includes a protection recess having a depth enough to house the conductive bonding material having a first thickness formed in the first print area.

With this configuration, even when printing in the first print area is performed prior to printing in the second print area, the printing in the second print area can be performed while avoiding influences on the conductive bonding material formed in the first print area.

A method for printing a conductive bonding material according to the present invention is a method for printing a conductive bonding material, in which a conductive bonding material is printed onto a mounting substrate using a screen mask configured with a mask member having a first print area in which the conductive bonding material is printed onto the mounting substrate so as to have a first thickness and a second print area in which the conductive bonding material is printed onto the mounting substrate so as to have a second thickness that is thicker than the first thickness, the method including: a first print area printing step of printing the conductive bonding material onto the mounting substrate so as to have the first thickness by using the first print area; and a second print area printing step of printing the conductive bonding material onto the mounting substrate after the first print area printing step so as to have the second thickness by using the second print area.

With this configuration, it is possible to eliminate the influence of a step of the screen mask (mask member) created by the difference between the first thickness and the second thickness, and a conductive bonding material having different thicknesses can be printed onto the mounting substrate with ease and high accuracy.

Furthermore, in the method for printing a conductive bonding material of the present invention, it is preferable that in the first print area printing step, the mounting substrate is fixed with a first positioning portion for positioning the mounting substrate in a print position corresponding to the first print area, and in the second print area printing step, the mounting substrate is fixed with a second positioning portion for positioning the mounting substrate in a print position corresponding to the second print area.

With this configuration, the position of the mounting substrate can be fixed with high accuracy in the first print area printing step and the second print area printing step, and thus highly accurate printing can be performed in the first print area and the second print area in different steps.

Another method for printing a conductive bonding material according to the present invention is a method for printing a conductive bonding material, in which a conductive bonding material is printed onto a mounting substrate using a screen mask configured with a mask member having a first print area in which the conductive bonding material is printed onto the mounting substrate so as to have a first thickness and a second print area in which the conductive bonding material is printed onto the mounting substrate so as to have a second thickness that is thicker than the first thickness, the method including: a plural print area concurrent printing step of printing the conductive bonding material in the first print area so as to have the first thickness concurrently with the conductive bonding material in the second print area so as to have the second thickness.

With this configuration, it is possible to print a conductive bonding material having different thicknesses onto a mounting substrate with ease, high accuracy and good productivity.

Furthermore, in the method for printing a conductive bonding material of the present invention, it is preferable that a squeegee used to print the conductive bonding material onto the mounting substrate has a squeegee step portion corresponding to a border step portion of the mask member located between the first print area and the second print area.

With this configuration, the pressure applied to the screen mask can be made uniform, and it is thus possible to print the conductive bonding material onto the mounting substrate with good uniformity.

A mounting method of mounting devices according to the present invention is a mounting method of mounting devices, in which a first mounting device mounted in a first bonding form and a second mounting device mounted in a second bonding form that is different from the first bonding form are mounted on a mounting substrate with a conductive bonding material, the method including: a conductive bonding material printing step of printing the conductive bonding material onto the mounting substrate using a screen mask having a first print area in which the conductive bonding material is printed onto the mounting substrate so as to have a first thickness and a second print area in which the conductive bonding material is printed onto the mounting substrate so as to have a second thickness that is thicker than the first thickness; a mounting device placing step of placing the first mounting device and the second mounting device on the conductive bonding material printed to have the first thickness and the conductive bonding material printed to have the second thickness, respectively; and a mounting device bonding step of melting and solidifying the conductive bonding material on which the first mounting device and the second mounting device are placed to bond the first mounting device and the second mounting device to the mounting substrate, wherein the first mounting device is a bumpless flip chip having flat terminals, and the second mounting device is a surface mounting device that is different from the bumpless flip chip.

With this configuration, because it is possible to collectively bond a first mounting device and a second mounting device of different mounting forms (bonding forms) onto a mounting substrate, mounting of mounting devices of different mounting forms can be performed with high efficiency and accuracy, and as a result, the productivity can be improved.

Furthermore, in the mounting method of mounting devices of the present invention, it is preferable that the mounting substrate includes first land portions onto which the conductive bonding material is to be printed and the first mounting device is to be bonded and second land portions onto which the conductive bonding material is to be printed and the second mounting device is to be bonded.

With this configuration, it is possible to configure first land portions and second land portions that correspond to a first mounting device and a second mounting device, respectively, and thus appropriate land portions corresponding to respective mounting devices can be formed.

Furthermore, in the mounting method of mounting devices of the present invention, it is possible that the first land portion is made larger than the flat terminal as viewed from above and the conductive bonding material printed on the first land portion is made larger than the flat terminal as viewed from above.

With this configuration, the adhesion of the conductive bonding material is allowed to act on the first mounting device in a self-alignment manner, and thus the first mounting device can be bonded to the conductive bonding material (the first land portions) with ease and high accuracy, and as a result, it is possible to improve the productivity.

Furthermore, in the mounting method of mounting devices of the present invention, it is preferable that a distance between centers of the flat terminals adjacent to each other is made smaller than a distance between centers of the first land portions adjacent to each other that correspond to the respective flat terminals.

With this configuration, when bonding is performed using the conductive bonding material, the bonding of the first mounting device can be reinforced by the adhesion of the conductive bonding material to the first mounting device, making it possible to position the first mounting device in a self-alignment manner, and as a result, the mounting of the first mounting device can be performed with good productivity.

Furthermore, in the mounting method of mounting devices of the present invention, it is preferable that the flat terminals and the first land portions are disposed such that a polygon formed by centers of the conductive bonding material portions printed on a plurality of the first land portions is made larger than a polygon formed by centers of a plurality of the flat terminals.

With this configuration, even when mounting a first mounting device having three or more terminals, it is possible to reliably mount the first mounting device onto a mounting substrate with ease and high accuracy.

Furthermore, in the mounting method of mounting devices of the present invention, the mounting substrate may be configured to include a groove between the first land portions that are adjacent to each other.

With this configuration, the flow of the conductive bonding material can be suppressed by the groove, and it is thus possible to reduce short circuit defects when bonding (a mounting device bonding step), and the mounting device can be mounted with good yield.

A mounting substrate according to the present invention is a mounting substrate including a plurality of first land portions to which flat terminals of a bumpless flip chip are to be bonded with a conductive bonding material and a plurality of second land portions to which a surface mounting device of a bonding form that is different from that of the bumpless flip chip is to be bonded with the conductive bonding material, wherein a groove is disposed between the first land portions adjacent to each other.

With this configuration, contact of the conductive bonding material between flat terminals of the bumpless flip chip can be prevented, and a mounting substrate having a high bonding yield can be obtained.

### BRIEF DESCRIPTION OF THE DRAWINGS

FIG. 1 is a configuration diagram conceptually illustrating a screen mask according to Embodiment 1 of the present invention, and the relationship between a screen mask, a mounting substrate and a conductive bonding material in a method for printing a conductive bonding material according to Embodiment 1 of the present invention.

FIG. 2 is a configuration diagram conceptually illustrating a screen mask according to a variation of Embodiment 1 of the present invention, and a screen mask in a method for printing a conductive bonding material according to a variation of Embodiment 1 of the present invention.

FIG. 3 is a perspective view conceptually illustrating a variation of a screen mask according to Embodiment 2 of the present invention.

FIG. 4A is a configuration diagram conceptually illustrating a screen mask according to Embodiment 3 of the present invention, and the relationship between a screen mask, a mounting substrate and a conductive bonding material in a method for printing a conductive bonding material according to Embodiment 3 of the present invention, and shows a case in which printing in a first print area is performed first.

FIG. 4B is a configuration diagram conceptually illustrating a screen mask according to Embodiment 3 of the present invention, and the relationship between a screen mask, a mounting substrate and a conductive bonding material in a method for printing a conductive bonding material according to Embodiment 3 of the present invention, and shows a case in which printing in a second print area is performed subsequent to the printing in a first print area.

FIG. 5 is a side view conceptually illustrating a mounting substrate according to Embodiment 4 of the present embodiment, on which a conductive bonding material has been printed.

FIG. 6A is a diagram conceptually illustrating a state in the middle of a process of mounting a first mounting device onto a conductive bonding material printed on a mounting substrate according to Embodiment 5 of the present invention, and is a see-through plan view illustrating the positional relationship of the constituent elements.

FIG. 6B is a diagram conceptually illustrating a state in the middle of a process of mounting a first mounting device onto a conductive bonding material printed on a mounting substrate according to Embodiment 5 of the present invention, and is an enlarged view of a cross section taken along the line B-B of FIG. 6A.

FIG. 7A is a process diagram illustrating a step of a mounting method of mounting devices according to Embodiment 6 of the present invention, and is a side view illustrating a state of a prepared mounting substrate.

FIG. 7B is a process diagram illustrating a step of a mounting method of mounting devices according to Embodiment 6 of the present invention, and is a side view illustrating a state of a conductive bonding material printing step of printing a conductive bonding material onto the mounting substrate.

FIG. 7C is a process diagram illustrating a step of a mounting method of mounting devices according to Embodiment 6 of the present invention, and is a cross-sectional view illustrating a state of a mounting device placing step of placing mounting devices onto the conductive bonding material.

FIG. 7D is a process diagram illustrating a step of a mounting method of mounting devices according to Embodiment 6 of the present invention, and is a cross-sectional view illustrating a state of a mounting device bonding step of melting and solidifying the conductive bonding material to bond the mounting devices to the mounting substrate.

FIG. 8A is a process diagram illustrating a step of conventional flip-chip mounting, and is a side view illustrating a state of a mounting substrate.

FIG. 8B is a process diagram illustrating a step of conventional flip-chip mounting, and is a side view illustrating a state of a positioning step of positioning a flip chip to the mounting substrate.

FIG. 8C is a process diagram illustrating a step of conventional flip-chip mounting, and is a side view illustrating a state of a flip chip bonding step of bonding the Rip chip to land portions of the mounting substrate.

FIG. 8D is a process diagram illustrating a step of conventional flip-chip mounting, and is a side view illustrating a state of a flip chip fixing step of forming a fixing portion between the flip chip bonded to the mounting substrate and the mounting substrate to fix the flip chip.

FIG. 9A is a process diagram illustrating a step of a conventional process of mounting a flip-chip and a surface mounting device onto a single mounting substrate, and is a side view illustrating a state of a prepared mounting substrate.

FIG. 9B is a process diagram illustrating a step of a conventional process of mounting a flip-chip and a surface mounting device onto a single mounting substrate, and is a side view illustrating a state of a conductive bonding material printing step of printing a conductive bonding material corresponding to a surface mounting device onto a mounting substrate.

FIG. 9C is a process diagram illustrating a step of a conventional process of mounting a flip-chip and a surface mounting device onto a single mounting substrate, and is a side view illustrating a state of a flux preparing step of preparing a flux to be transferred to solder bumps of a flip chip.

FIG. 9D is a process diagram illustrating a step of a conventional process of mounting a flip-chip and a surface mounting device onto a single mounting substrate, and is a side view illustrating a state of a flux transferring step of transferring the flux to solder bumps of a flip chip.

FIG. 9E is a process diagram illustrating a step of a conventional process of mounting a flip-chip and a surface mounting device onto a single mounting substrate, and is a side view illustrating a state of a mounting device placing step of placing the flip chip and a surface mounting device onto the mounting substrate.

FIG. 9F is a process diagram illustrating a step of a conventional process of mounting a flip-chip and a surface mounting device onto a single mounting substrate, and is a side view illustrating a state of a mounting device bonding step of bonding the flip chip and the surface mounting device onto the mounting substrate.

### DESCRIPTION OF THE PREFERRED EMBODIMENTS

Hereinafter, embodiments of the present invention will be described with reference to the accompanying drawings.

### Embodiment 1

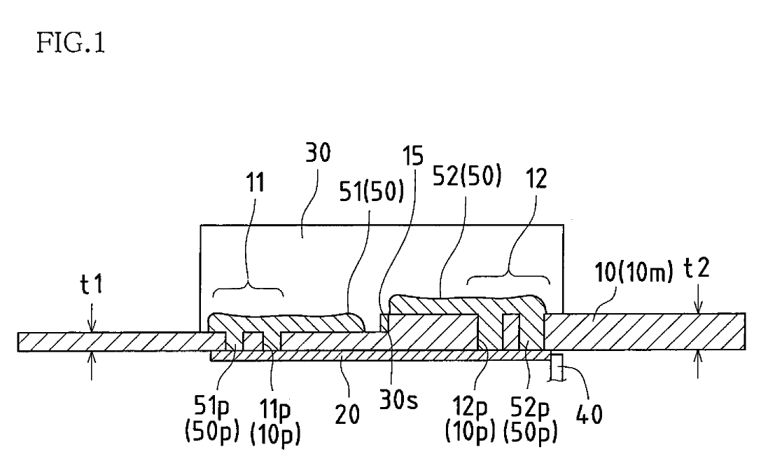

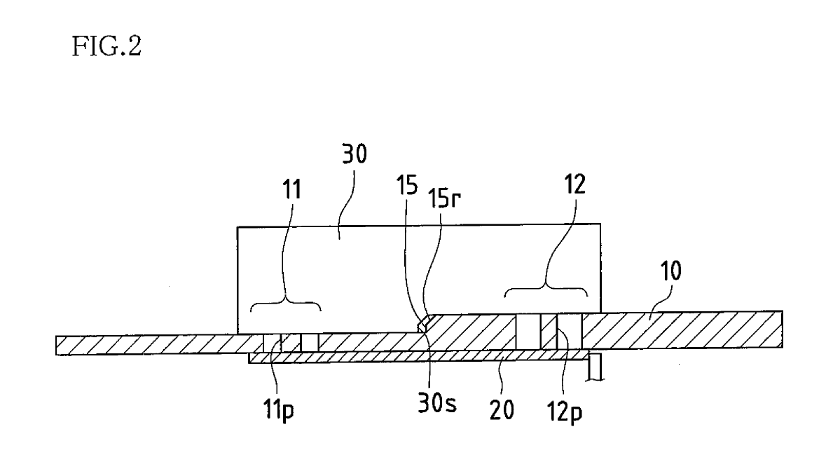

A screen mask and a method for printing a conductive bonding material according to the present embodiment will be described with reference to FIGS. 1 and 2. That is, an embodiment in which a conductive bonding material is printed onto a mounting substrate by using a screen mask will be described.

FIG. 1 is a configuration diagram conceptually illustrating a screen mask according to Embodiment 1 of the present invention, and the relationship between a screen mask, a mounting substrate and a conductive bonding material in a method for printing a conductive bonding material according to Embodiment 1 of the present invention.

A screen mask 10 according to the present embodiment includes a mask member 10m, in which a print pattern 10p (a first print area pattern 11p and a second print area pattern 12p) is formed, that is used to print a conductive bonding material 50 (a conductive bonding material 51 supplied (applied) to a first print area 11, and a conductive bonding material 52 supplied (applied) to a second print area 12) onto a mounting substrate 20. The conductive bonding material 50 can be, but is not limited to, for example, solder, a silver paste (conductive adhesive), etc.

Hereinafter, when it is unnecessary to distinguish between the first print area pattern 11p and the second print area pattern 12p, they are sometimes referred to simply as a print pattern 10p. Likewise, when it is unnecessary to distinguish between the conductive bonding material 51 and the conductive bonding material 52, they are sometimes referred to simply as a conductive bonding material 50.

The mask member 10m includes the first print area 11 in which the conductive bonding material 51 is printed onto the mounting substrate 20 so as to have a first thickness t1, and the second print area 12 in which the conductive bonding material 52 is printed onto the mounting substrate 20 so as to have a second thickness t2 that is thicker than the first thickness t1. That is, the mask member 10m is configured such that the first print area 11 has a substantially first thickness t1, and the second print area 12 has a substantially second thickness t2.

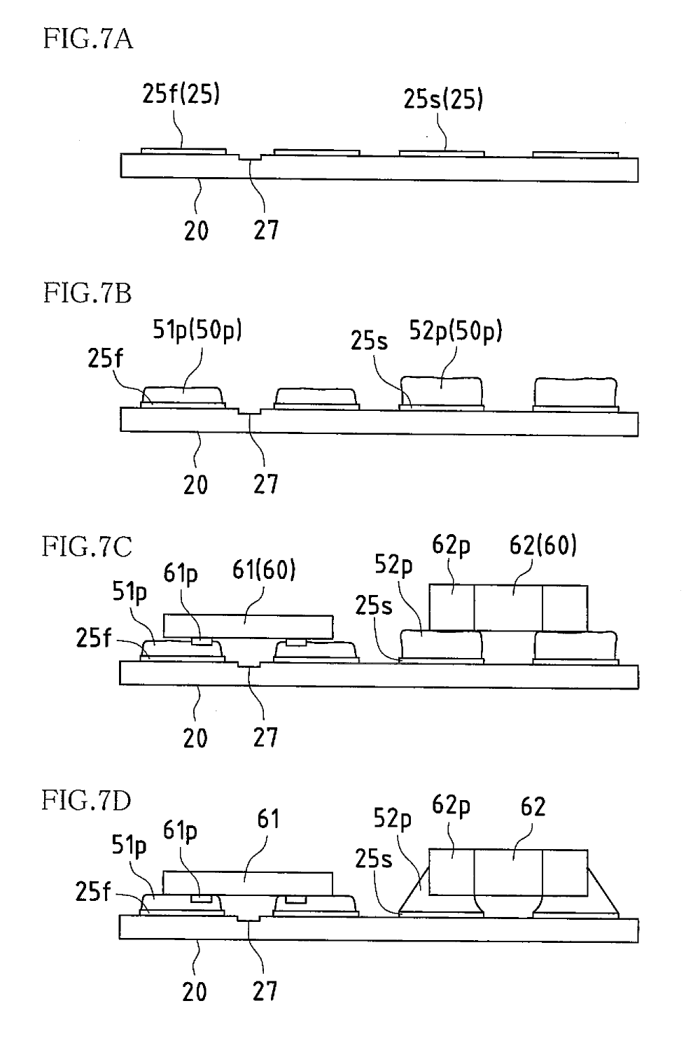

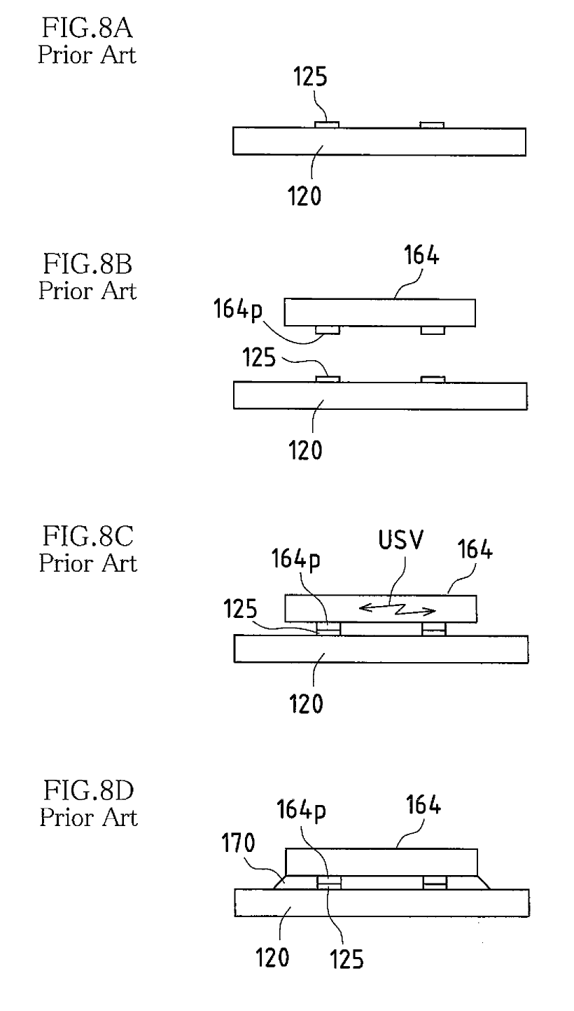

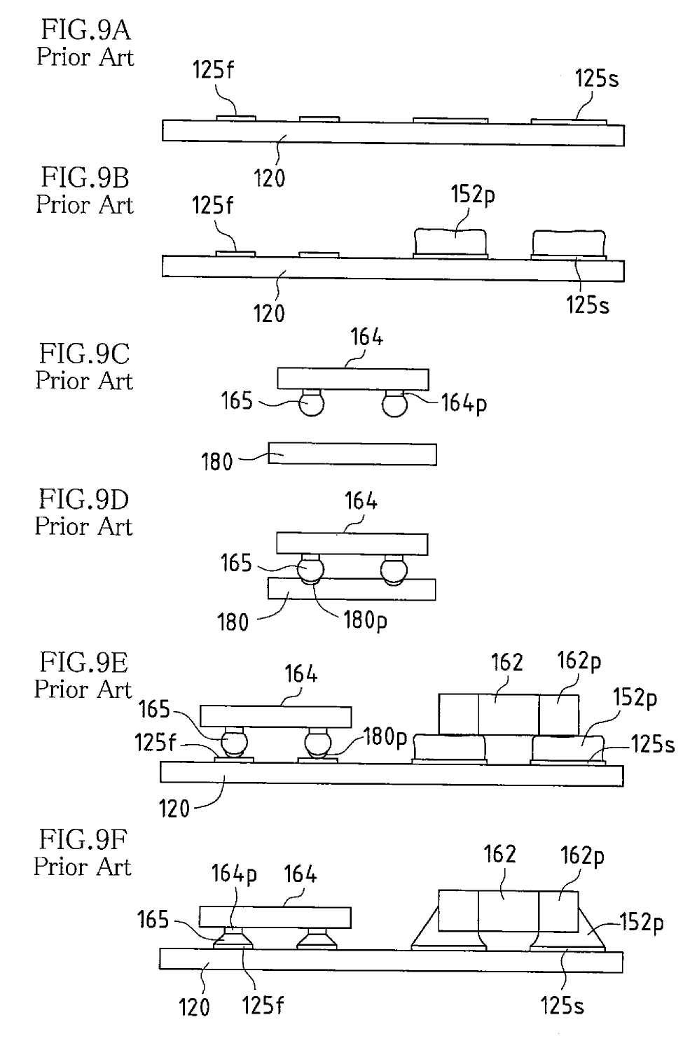

Accordingly, it is possible to form a conductive bonding material 50p (a conductive bonding material 51p and a conductive bonding material 52p) patterned to have thicknesses (a first thickness t1 and a second thickness t2) corresponding to the type (mounting form, bonding form) of mounting devices 60 (a first mounting device 61 mounted in a first bonding form, and a second mounting device 62 mounted in a second bonding form; see FIGS. 7A to 7D) to be mounted onto the mounting substrate 20. As a result, the conductive bonding material 50 can be formed with good work efficiency.

Hereinafter, when it is unnecessary to distinguish between the first mounting device 61 and the second mounting device 62, they are sometimes referred to simply as mounting devices 60.

A method for printing a conductive bonding material according to the present embodiment is a method for printing a conductive bonding material 50 onto a mounting substrate 20 using a screen mask 10 including a mask member 10m having a print pattern 10p (a first print area pattern 11p and a second print area pattern 12) having a first print area 11 in which a conductive bonding material 51 is printed onto the mounting substrate 20 so as to have a first thickness t1 and a second print area 12 in which a conductive bonding material 52 is printed onto the mounting substrate 20 so as to have a second thickness t2 that is thicker than the first thickness t1.

The method for printing a conductive bonding material of the present embodiment involves a plural print area concurrent printing step of printing, in the first print area 11, the conductive bonding material 50 onto the mounting substrate 20 so as to have a first thickness t1 concurrently with printing, in the second area 12, the conductive bonding material 50 onto the mounting substrate 20 so as to have a second thickness t2.

That is, printing of conductive bonding material 51p in the first print area 11 and printing of conductive bonding material 52p in the second print area 12 are performed simultaneously in a collective manner.

Accordingly, a conductive bonding material 50 of different thickness (the conductive bonding material 61p and the conductive bonding material 52p) can be printed onto the mounting substrate 20 with ease, high accuracy and good productivity.

The printing of conductive bonding material 50 is executed by pressing the conductive bonding material 50 placed (applied) onto the screen mask 10 against the mounting substrate 20 with a known squeegee 30.

In the present embodiment, as already described above, the conductive bonding material 50 is placed and printed simultaneously on the first print area 11 configured to have a first thickness t1 and the second print area 12 configured to have a second thickness t2. At this time, considering work efficiency, one squeegee 30 is used to perform the printing in the first print area 11 and the second print area 12.

That is, the squeegee 30 used to print the conductive bonding material 50 onto the mounting substrate 20 has a squeegee step portion 30s that corresponds to a border step portion 15 of the screen mask 10 (mask member 10m) located between the first print area 11 and the second print area 12. Accordingly, because the pressure applied to the screen mask 10 can be made uniform in the first print area 11 and the second print area 12, it is thus possible to print the conductive bonding material 50 onto the mounting substrate 20 with good uniformity.

In the present embodiment, a positioning portion 40 for fixing the position of the mounting substrate 20 when the conductive bonding material 50 is printed onto the mounting substrate 20 is provided.

FIG. 2 is a configuration diagram conceptually illustrating a screen mask according to a variation of Embodiment 1 of the present invention, and a screen mask in a method for printing a conductive bonding material according to a variation of Embodiment 1 of the present invention.

In the present embodiment, because printing is performed simultaneously in the first print area 11 and the second print area 12 in a collective manner, the squeegee 30 may be offset at the border step portion 15 in the printing step (a plural print area concurrent printing step), causing abrasion to occur in the squeegee 30, and, as a result, failing to secure a stable print performance for the mounting substrate 20.

Accordingly, a screen mask 10 is configured such that the border step portion 15 located between the first print area 11 and the second print area 12 has a chamfer portion 15r, in order to prevent abrasion from occurring in the squeegee 30. That is, with this configuration, it is possible to secure durability and print stability while suppressing the abrasion of the squeegee 30 used when forming the conductive bonding material 50.

### Embodiment 2

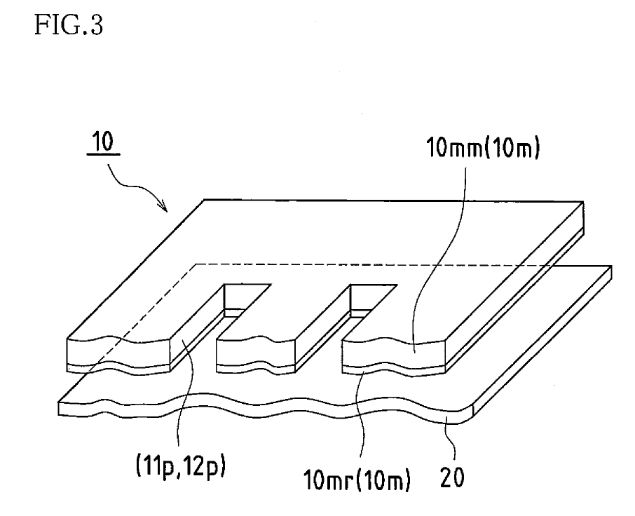

A screen mask according to the present embodiment will be described with reference to FIG. 3. That is, a variation of the screen mask 10 used in Embodiment 1 will be described as Embodiment 2. The basic configuration of the screen mask 10 is the same as that of Embodiment 1, and thus only differences will be described.

FIG. 3 is a perspective view conceptually illustrating a variation of a screen mask according to Embodiment 2 of the present invention.

A screen mask 10 (mask member 10m) of the present embodiment includes a metal material layer 10mm and a resin material layer 10mr formed on the surface of the metal material layer 10mm that faces the mounting substrate 20. Accordingly, the adhesion of the mask member 10m to the mounting substrate 20 can be improved. That is, a screen mask 10 that can conform to the protrusions and recesses of the mounting substrate 20 can be obtained.

The metal material layer 10mm is configured with, for example, a stainless steel sheet or mesh. In the metal material layer 10mm, a first print area pattern 11p and a second print area pattern 12 as shown in Embodiment 1 are formed.

The resin material layer 10mm is formed by coating the metal material layer 10mm with a resin in the same pattern as that of the metal material layer 10mm. The resin used for coating can be, for example, urethane, polyimide, polytetrafluoroethylene or the like, and is applied to have a thickness of about 5 to 50 μm.

### Embodiment 3

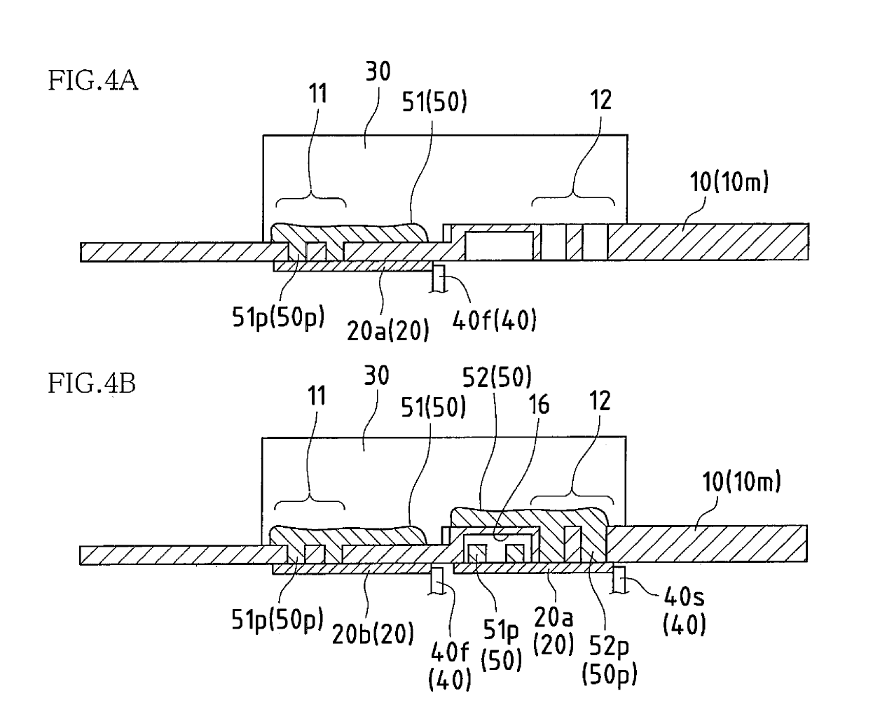

A screen mask and a method for printing a conductive bonding material according to the present embodiment will be described with reference to FIGS. 4 A and 4B. That is, while in Embodiment 1, the printing of conductive bonding material 51p in a first print area 11 and the printing of conductive bonding material 52p in a second print area 12 are performed simultaneously in a collective manner, in the present embodiment, the printing in a first print area 11 and the printing in a second print area 12 are performed in turn.

FIG. 4A is a configuration diagram conceptually illustrating a screen mask according to Embodiment 3 of the present invention, and the relationship between a screen mask, a mounting substrate and a conductive bonding material in a method for printing a conductive bonding material according to Embodiment 3 of the present invention, and shows a case in which printing in a first print area is performed first. FIG. 4 B shows a case in which printing in a second print area is performed subsequent to the printing in a first print area.

The basic configuration of the screen mask and the method for printing a conductive bonding material of the present embodiment is the same as that of Embodiment 1, and thus only differences will be described. In the present embodiment, a conductive bonding material 51 for a first print area 11 (a patterned conductive bonding material 51p) is printed first (a first print area printing step), and after that, a conductive bonding material 52 (a patterned conductive bonding material 52p) is printed (a second print area printing step), which is different from Embodiment 1.

Another difference from Embodiment 1 is that a protection recess 16 for housing the conductive bonding material 51p that has already been printed is formed in a second print area 12 so as to separately perform the printing step for a first print area 11 and the printing step for a second print area 12.

FIG. 4 A shows a state of a step in which printing in a first print area 11 is performed first for the mounting substrate 20 (a first print area printing step).

Specifically, first, a first mounting substrate 20a is disposed to correspond to a first print area 11, and then fixed with a first positioning portion 40f (positioning portion 40). A conductive bonding material 50 (conductive bonding material 51) is supplied onto the screen mask 10 so as to correspond to the first print area 11, and a conductive bonding material 51p patterned in the first print area 11 is printed onto the mounting substrate 20a with a squeegee 30.

Because a mounting substrate 20a is not disposed in a second print area 12 in the first print area printing step, a conductive bonding material 52 (conductive bonding material 52p) is not printed.

FIG. 4 B shows a state of a step in which printing in a second print area 12 is performed for the mounting substrate 20 subsequently to the printing in a first print area was performed (a second print area printing step).

Specifically, next, a mounting substrate 20a in which the conductive bonding material 51p has been printed is disposed to correspond to the second print area 12, and then fixed with a second positioning portion 40s (positioning portion 40). A conductive bonding material 50 (conductive bonding material 52) is supplied onto the screen mask 10 so as to correspond to the second print area 12, and a conductive bonding material 52p patterned in the second print area 12 is printed onto the mounting substrate 20a with the squeegee 30. Herein, when it is unnecessary to distinguish between the first positioning portion 40f and the second positioning portion 40s, they are sometimes referred to as positioning portions 40.

Because the conductive bonding material 51p is housed in the protection recess 16 in the second print area printing step, there is no influence of the conductive bonding material 52. In addition, the second print area printing step can be performed in the same manner as the processing of the mounting substrate 20a, except that the second mounting substrate 20b is disposed to correspond to the first print area 11, and then fixed with the first positioning portion 40f, and it is thus possible to perform printing in substantially the same unit of time as Embodiment 1.

As described above, the method for printing a conductive bonding material of the present invention involves: when printing a conductive bonding material 50 (a conductive boding material 51 and a conductive bonding material 52) onto a mounting substrate 20 (e.g., a conductive substrate 20a) using a screen mask 10 configured with a mask member 10m including a first print area 11 having a first thickness t1 and a second print area 12 having a second thickness t2 that is thicker than the first thickness t1, a first print area printing step of printing a conductive bonding material 50 (conductive bonding material 61, that is, conductive bonding material 51p) onto the mounting substrate 20 so as to have a first thickness t1 using the first print area 11; and a second print area printing step of, after the first print area printing step, printing a conductive bonding material 50 (conductive bonding material 52, conductive bonding material 52p) onto the mounting substrate 20 (e.g., mounting substrate 20a) so as to have a second thickness t2 using the second print area 12.

Accordingly, it is possible to eliminate the influence of a step of the screen mask 10 (mask member 10m) created by the difference between the first thickness t1 and the second thickness t2, and a conductive bonding material 50 having different thicknesses (conductive bonding material 51p and conductive bonding material 52p) can be printed onto the mounting substrate 20 with ease and high accuracy.

Furthermore, in the first print area printing step, the mounting substrate 20 is fixed with the first positioning portion 40f for positioning the mounting substrate 20 in the print position corresponding to the first print area 11, and in the second print area printing step, the mounting substrate 20 is fixed with the second positioning portion 40s for positioning the mounting substrate 20 in the print position corresponding to the second print area 12.

Accordingly, the position of the mounting substrate 20 can be fixed with high accuracy in the first print area printing step and the second print area printing step, and thus highly accurate printing can be performed in the first print area 11 and the second print area 12 in different steps.

In the screen mask 10 of the present embodiment, the second print area 12 includes a protection recess 16 having a depth enough to house the conductive bonding material 50 (conductive bonding material 51p) having a first thickness t1 that has been formed in the first print area 11.

Accordingly, even when the printing in the first print area 11 is performed prior to the printing in the second print area 12, it is possible to perform the printing in the second print area 12 while avoiding influences on the conductive bonding material 50 (conductive bonding material 51p) that has been formed in the first print area 11.

### Embodiment 4

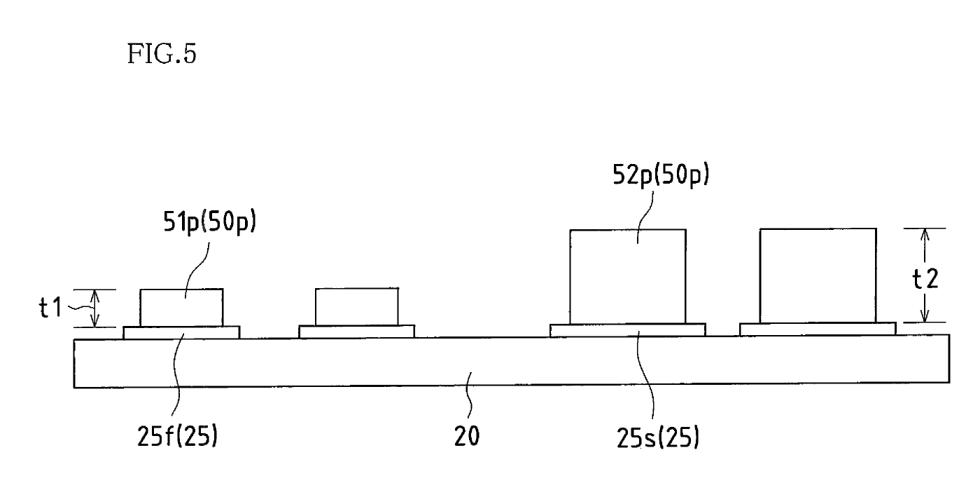

A mounting substrate according to the present embodiment will be described with reference to FIG. 5. That is, a mounting substrate 20 of the present embodiment is a mounting substrate 20 in which a conductive bonding material 50 is printed by using the screen mask and the method for printing a conductive bonding material according to any one of Embodiments 1 to 3.

FIG. 5 is a side view conceptually illustrating a mounting substrate according to Embodiment 4 of the present embodiment, in which a conductive bonding material has been printed.

The basic configuration of the mounting substrate 20 of the present embodiment is the same as that of the mounting substrates 20 described in Embodiments 1 and 3, and thus only differences will be described.

The mounting substrate 20 of the present embodiment includes a conductive bonding material 51p having a first thickness t1 that has been printed to correspond to the first print area 11, and a conductive bonding material 52p having a second thickness t2 that has been printed to correspond to the second print area 12. The first thickness t1 and the second thickness t2 may change with time, with respect to those immediately after printing, but such changes are included as the first thickness t1 and the second thickness t2. Furthermore, the first thickness t1 and the second thickness t2 may further change because melt heating is performed in the step of mounting a mounting device 60.

On the mounting substrate 20, first land portions 25f and second land portions 25s are formed in advance to correspond to an area in which a conductive bonding material 51p is to be printed and an area in which a conductive bonding material 52p is to be printed, respectively.

That is, the conductive bonding material 51p is printed onto the first land portions 25f, and the conductive bonding material 52p is printed onto the second land portions 25s. Hereinafter, when it is unnecessary to distinguish between the first land portions 25f and the second land portions 25s, they are sometimes referred to simply as land portions 25. The land portions 25 are formed by, for example, patterning a copper foil by a known patterning technique.

### Embodiment 5

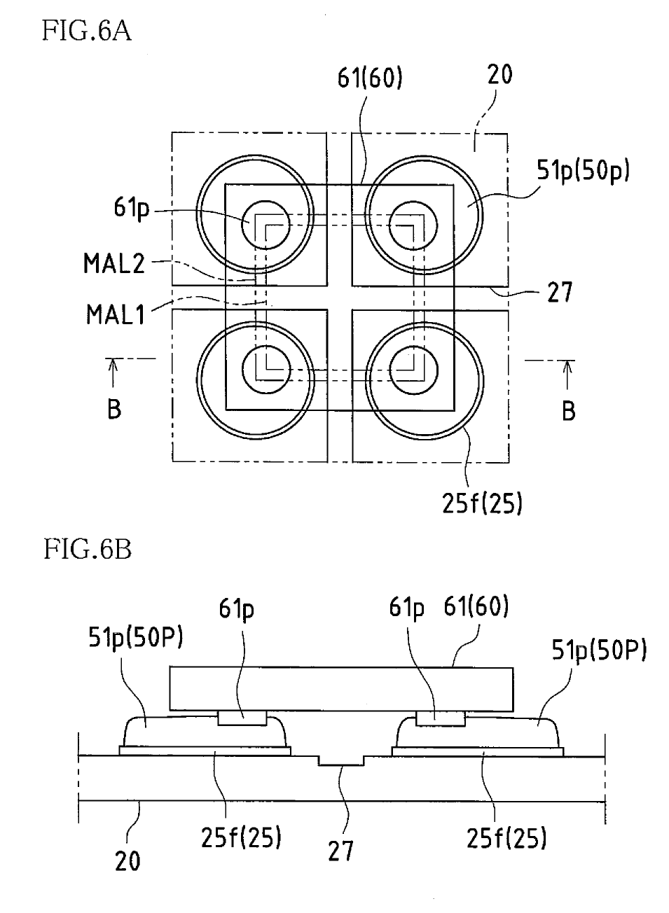

A method for mounting a first mounting device onto a mounting substrate according to the present embodiment will be described with reference to FIGS. 6A and 6B. That is, an embodiment in which a first mounting device 61 is mounted (placed) on the conductive bonding material 51 (conductive bonding material 51p) printed on a mounting substrate 20 according to any one of Embodiments 1 to 4 will be described. The basic configuration is the same as that of Embodiments 1 to 4, and thus only differences will be described.

FIG. 6A is a diagram conceptually illustrating a state in the middle of a process of mounting a first mounting device onto a conductive bonding material printed on a mounting substrate according to Embodiment 5 of the present invention, and is a see-through plan view illustrating the positional relationship of the constituent elements. FIG. 6B is an enlarged view of a cross section taken along the line B-B of FIG. 6A.

A conductive bonding material 50p (conductive bonding material 51p) corresponding to a first print area 11 is printed on first land portions 25f of a mounting substrate 20 (a conductive bonding material printing step). As described above, the conductive bonding material 51p is printed by patterning a conductive bonding material 50 on the mounting substrate 20 using a screen mask 10 in the plural print area concurrent printing step of Embodiment 1 or the first print area printing step of Embodiment 3. That is, the conductive bonding material 51p is printed onto the first land portions 25f so as to have a first thickness t1.

A first mounting device 61 is placed on the conductive bonding material 51p (a mounting device placing step). Accordingly, the first mounting device 61 is placed on the first land portions 25f. The first mounting device 61 can be, for example a bumpless flip chip, and has flat terminals 61p as terminals. That is, the first mounting device 61 is a mounting device that is to be flip-chip mounted.

Because the first mounting device 61 is a bumpless flip chip in which flat terminals 61p (pad electrodes) have been formed rather than protruding terminals (bump electrodes), the step of forming bumps can be eliminated, and thus the process of the mounting method of a mounting device can be simplified.

A first land portion 22f is made larger than a flat terminal 61p (flip chip pad) as viewed from above, and the conductive bonding material 61p printed onto the first land portion 25f is made larger than the flat terminal 61p as viewed from above. Accordingly, when bonding the flat terminal 61p to the conductive bonding material 51p (the mounting substrate 20, the first land portion 25f) by melting and solidifying the conductive bonding material 51p in a mounting device bonding step described later (see Embodiment 6), the adhesion of the conductive bonding material 51p is allowed to act on the first mounting device 61 in a self-alignment manner, and thus the first mounting device 61 can be bonded to the conductive bonding material 51p (the first land portions 250 with ease and high accuracy, and as a result, it is possible to improve the productivity.

Furthermore, the distance between the centers of relatively adjacent flat terminals 51p (e.g., the length of a side of a polygon MAL1 being a quadrilateral) is made shorter than the distance between the centers of relatively adjacent first land portions 25f corresponding to respective flat terminals 61p (e.g., the length of a side of a polygon MAL2 being a quadrilateral).

Accordingly, when bonding the first mounting device 61 with the conductive bonding material 51p, the bonding of the first mounting device 61 can be reinforced by the adhesion of the conductive bonding material 51p to the first mounting device 61, making it possible to position the first mounting device 61 in a self-alignment manner, and as a result, the mounting of the first mounting device 61 can be performed with good productivity. That is, even when a flip chip type mounting device 60 (first mounting device 61), which is difficult to position because it needs to be flipped for mounting (bonding), is used, it is possible to secure extremely high positioning accuracy.

The flat terminals 61p and the first land portions 25f are disposed such that a polygon MAL2, formed by the centers of a plurality (three or more, the number of vertices of the polygon MAL2 being, for example, a quadrilateral in the present embodiment) of the conductive bonding material portions 51p printed on the first land portions 25f, is larger than a polygon MAL1 formed by the centers of a plurality (three or more, the number of vertices of the polygon MAL1 being, for example, a quadrilateral in the present embodiment) of flat terminals 61p.

Accordingly, even when mounting a first mounting device 61 having three or more terminals, it is possible to reliably mount the first mounting device 61 onto a mounting substrate 20 with ease and high accuracy.

In the mounting substrate 20, a groove 27 is disposed between relatively adjacent first land portions 25f. With this, the flow of the conductive bonding material 51p can be suppressed by the groove 27, and it is thus possible to reduce short circuit defects when bonding (a mounting device bonding step), and the mounting device 61 can be mounted with good yield.

### Embodiment 6

A mounting substrate and a mounting method of mounting devices, in which a plurality of types of mounting devices that employ different mounting forms (bonding forms) are mounted onto a mounting substrate, according to the present embodiment will be described with reference to FIGS. 7A to 7D. That is, an embodiment in which a first mounting device 61 and a second mounting device 62 are placed and mounted (bonded) on the conductive bonding material 50 (conductive bonding material 50p) printed onto a mounting substrate 20 according to any one of Embodiments 1 to 4 will be described.

FIGS. 7A to 7D are process diagrams illustrating the steps of a mounting method of mounting devices according to Embodiment 6 of the present invention. FIG. 7A is a side view illustrating a state of a prepared mounting substrate. FIG. 7B is a side view illustrating a state of a conductive bonding material printing step of printing a conductive bonding material onto a mounting substrate. FIG. 7C is a cross-sectional view illustrating a state of a mounting device placing step of placing mounting devices onto the conductive bonding material. FIG. 7D is a cross-sectional view illustrating a state of a mounting device bonding step of melting and solidifying the conductive bonding material to bond the mounting devices to the mounting substrate.

The basic configuration is the same as that of Embodiments 1 to 5, and thus only differences will be described.

On a mounting substrate 20 of the present embodiment, first land portions 25f onto which a first mounting device 61 is to be mounted (bonded) and second land portions 25s onto which a second mounting device 62 is to be mounted (bonded) are formed (FIG. 7A). That is, the mounting substrate 20 includes the first land portions 25f onto which a conductive bonding material 51p is to be printed and a first mounting device 61 is to be bonded and the second land portions 25s onto which a conductive bonding material 52p is to be printed and a second mounting device 62 is to be bonded.

Accordingly, the first land portions 25f and the second land portions 25s can be configured to correspond to the first mounting device 61 and the second mounting device 62, respectively, and thus appropriate land portions 25 corresponding to respective mounting devices (first mounting device 61 and second mounting device 62) can be formed.

The conductive bonding material 51p is formed on the first land portions 25f by printing a conductive bonding material 50, and the conductive bonding material 52p is formed on the second land portions 25s by printing the conductive bonding material 50 (FIG. 7B: a conductive bonding material printing step).

That is, the conductive bonding material 50 (conductive bonding material 51p and conductive bonding material 52p) is printed onto the mounting substrate 20 using a screen mask 10 having a first print area 11 in which the conductive bonding material 51p patterned by printing the conductive bonding material 50 onto the mounting substrate 20 so as to have a first thickness t1 is formed, and a second print area 12 in which the conductive bonding material 52p patterned by printing the conductive bonding material 50 onto the mounting substrate 20 so as to have a second thickness t2 that is thicker than the first thickness t1 is formed (a conductive bonding material printing step).

The conductive bonding material printing step is executed in, namely, the plural print area concurrent printing step of Embodiment 1, or the first print area printing step and the second print area printing step of Embodiment 3.

As already described in Embodiment 5, a first land portion 25f is made larger than a flat terminal 61p as viewed from above, and the conductive bonding material 51p printed on the first land portion 25f is made larger than the flat terminal 61p as viewed from above. Accordingly, the adhesion of the conductive bonding material 51p is allowed to act on the first mounting device 61 in a self-alignment manner, and thus the first mounting device 61 can be bonded to the conductive bonding material 51p (the first land portions 25f) with ease and high accuracy, and as a result, it is possible to improve the productivity.

A first mounting device 61 and a second mounting device 62 are placed through positioning on the mounting substrate 20 on which the conductive bonding material 51p and the conductive bonding material 52p have been printed (FIG. 7C). Specifically, the first mounting device 61 is placed on the conductive bonding material 51p printed to have a first thickness t1, and the second mounting device 62 is placed on the conductive bonding material 52p printed to have a second thickness t2 (a mounting device placing step). In this placing step, the first mounting device 61 and the second mounting device 62 are pressed with an appropriate pressure so as to be in a provisionally fixed state.

Accordingly, the flat terminals 61p of the first mounting device 61 are positioned to the conductive bonding material 51p, and the bonding terminals 62p of the second mounting device 62 are positioned to the conductive bonding material 52p.

The conductive bonding material 50p (the conductive bonding material 51p and the conductive bonding material 52p) on which the first mounting device 61 and the second mounting device 62 have been placed is melted and solidified (e.g., solder reflow) to bond the first mounting device 61 and the second mounting device 62 collectively to the mounting substrate 20 (FIG. 7D, a mounting device bonding step). The conditions for melting and solidification can be set as appropriate according to the material of the conductive bonding material 50.

In the present embodiment, as already described in Embodiment 5, the first mounting device 61 is a bumpless flip chip having flat terminals, and the second mounting device 62 is a common surface mounting device (SMD) configured in a mounting form (bonding form) that is different from that of the bumpless flip chip (first mounting device 61).

As described above, the mounting method of mounting devices of the present embodiment is a method in which a first mounting device 61 mounted in a first bonding form and a second mounting device 62 mounted in a second bonding form that is different from the first bonding form are mounted onto a mounting substrate 20 with a conductive bonding material 50p, and includes a conductive bonding material printing step, a mounting device placing step and a mounting device bonding step. The first mounting device 61 is a bumpless flip chip having flat terminals 61p, and the second mounting device 62 is a surface mounting device that is different from the bumpless flip chip.

Therefore, according to the present embodiment, a plurality of mounting devices (e.g., the first mounting device 61 and the second mounting device 62) of different mounting forms (bonding forms) can be collectively bonded to the mounting substrate 20, and as a result, the mounting devices 60 of different mounting forms can be mounted efficiently with high accuracy, and the productivity can be improved.

Furthermore, the mounting substrate 20 of the present embodiment includes a plurality of first land portions 25f to which flat terminals 61p of a bumpless flip chip (first mounting device 61) are to be bonded with a conductive bonding material 51p and a plurality of second land portions 25s to which a surface mounting device (second mounting device 62) of a bonding form that is different from that of the bumpless flip chip is to be bonded with a conductive bonding material 52p. Accordingly, contact of the conductive bonding material 51p between flat terminals 61p of the bumpless flip chip can be prevented, and it is thus possible to obtain a mounting substrate 20 having a high bonding yield.

A first mounting device 61 configured with a bumpless flip chip is made much smaller in size than a second mounting device 62 configured with a surface mounting device of a bonding form that is different from that of the bumpless flip chip, and it has been difficult to mount both devices on a single mounting substrate 20.

However, according to the present embodiment, the first mounting device 61 being a bumpless flip chip can be bonded by positioning it to the first land portions 25f and the conductive bonding material 51p in a self-alignment manner in the bonding step (the mounting device bonding step) of the second mounting device 62, and it is thus possible to mount the first mounting device 61 being a bumpless flip chip and the second mounting device 62 of a bonding form that is different from that of the first mounting device 61 on a single mounting substrate 20 with ease, high accuracy and high productivity, which has hitherto been difficult to achieve.

Although the present embodiment has been described in the context of the first mounting device 61 being a bumpless flip chip, the present embodiment can be equally applied to a first mounting device 61 being a device other than a bumpless flip chip that is made smaller in size than the second mounting device 62.

The present invention may be embodied in various other forms without departing from the spirit or essential characteristics thereof. The embodiments disclosed in this application are to be considered in all respects as illustrative and not limiting. The scope of the invention is indicated by the appended claims rather than by the foregoing description, and all modifications or changes that come within the meaning and range of equivalency of the claims are intended to be embraced therein.

What is claimed is:

1. A screen mask for printing a conductive bonding material onto a mounting substrate, comprising a mask member in which a print pattern is formed,
wherein the mask member includes:
a first print area in which the conductive bonding material is printed onto the mounting substrate so as to have a first thickness, and
a second print area in which the conductive bonding material is printed onto the mounting substrate so as to have a second thickness that is thicker than the first thickness.

2. The screen mask according to claim 1,
wherein the mask member includes a metal material layer and a resin material layer formed on a surface of the metal material layer that faces the mounting substrate.

3. The screen mask according to claim 1,
wherein a border step portion located between the first print area and the second print area has a chamfer portion.

4. The screen mask according to claim 2,
wherein a border step portion located between the first print area and the second print area has a chamfer portion.

5. The screen mask according to any one of claims 1 to 4,
wherein the second print area includes a protection recess having a depth enough to house the conductive bonding material having the first thickness formed in the first print area.

6. A method for printing a conductive bonding material, in which a conductive bonding material is printed onto a mounting substrate using a screen mask configured with a mask member having a first print area in which the conductive bonding material is printed onto the mounting substrate so as to have a first thickness and a second print area in which the conductive bonding material is printed onto the mounting substrate so as to have a second thickness that is thicker than the first thickness, the method comprising:
a first print area printing step of printing the conductive bonding material onto the mounting substrate so as to have the first thickness by using the first print area; and
a second print area printing step of printing the conductive bonding material onto the mounting substrate after the first print area printing step so as to have the second thickness by using the second print area.

7. The method for printing a conductive bonding material according to claim 6,
wherein, in the first print area printing step, the mounting substrate is fixed with a first positioning portion for positioning the mounting substrate in a print position corresponding to the first print area, and
in the second print area printing step, the mounting substrate is fixed with a second positioning portion for positioning the mounting substrate in a print position corresponding to the second print area.

8. A method for printing a conductive bonding material, in which a conductive bonding material is printed onto a mounting substrate using a screen mask configured with a mask member having a first print area in which the conductive bonding material is printed onto the mounting substrate so as to have a first thickness and a second print area in which the conductive bonding material is printed onto the mounting substrate so as to have a second thickness that is thicker than the first thickness, the method comprising:
a plural print area concurrent printing step of printing the conductive bonding material in the first print area so as to have the first thickness concurrently with the conductive bonding material in the second print area so as to have the second thickness.

9. The method for printing a conductive bonding material according to any one of claims 6 to 8,
wherein a squeegee used to print the conductive bonding material onto the mounting substrate has a squeegee step portion corresponding to a border step portion of the mask member located between the first print area and the second print area.

10. A mounting method of mounting devices, in which a first mounting device mounted in a first bonding form and a second mounting device mounted in a second bonding form that is different from the first bonding form are mounted on a mounting substrate with a conductive bonding material, the method comprising:
a conductive bonding material printing step of printing the conductive bonding material onto the mounting substrate using a screen mask having a first print area in which the conductive bonding material is printed onto the mounting substrate so as to have a first thickness and a second print area in which the conductive bonding material is printed onto the mounting substrate so as to have a second thickness that is thicker than the first thickness;
a mounting device placing step of placing the first mounting device and the second mounting device on the conductive bonding material printed to have the first thickness and the conductive bonding material printed to have the second thickness, respectively; and
a mounting device bonding step of melting and solidifying the conductive bonding material on which the first mounting device and the second mounting device are placed to bond the first mounting device and the second mounting device to the mounting substrate,
wherein the first mounting device is a bumpless flip chip having flat terminals, and the second mounting device is a surface mounting device that is different from the bumpless flip chip.

11. The mounting method of mounting devices according to claim 10,
wherein the mounting substrate includes first land portions onto which the conductive bonding material is to be printed and the first mounting device is to be bonded and second land portions onto which the conductive bonding material is to be printed and the second mounting device is to be bonded.

12. The mounting method of mounting devices according to claim 11,
wherein the first land portion is made larger than the flat terminal as viewed from above and the conductive bonding material printed on the first land portion is made larger than the flat terminal as viewed from above.

13. The mounting method of mounting devices according to claim 11,
wherein a distance between centers of the flat terminals adjacent to each other is made smaller than a distance between centers of the first land portions adjacent to each other that correspond to the respective flat terminals.

14. The mounting method of mounting devices according to claim 13,
wherein the flat terminals and the first land portions are disposed such that a polygon formed by centers of the conductive bonding material portions printed on a plurality of the first land portions is made larger than a polygon formed by centers of a plurality of the flat terminals.

15. The mounting method of mounting devices according to any one of claims 11 to 14 wherein the mounting substrate includes a groove between the first land portions adjacent to each other.

16. A mounting substrate comprising a plurality of first land portions to which flat terminals of a bumpless flip chip are to be bonded with a conductive bonding material and a plurality of second land portions to which a surface mounting device of a bonding form that is different from that of the bumpless flip chip is to be bonded with the conductive bonding material,
wherein a groove is disposed between the first land portions adjacent to each other.
